(19) United States
(12) Patent Application Publication
(10) Pub. No.: US 2015/0187974 A1
(43) Pub. Date: Jul. 2, 2015

(54) SOLAR CELL MODULE AND MANUFACTURING METHOD THEREOF

(71) Applicant: LG INNOTEK CO., LTD., Seoul (KR)

(72) Inventor: Kyung Ho Kang, Seoul (KR)

(73) Assignee: LG INNOTEK CO., LTD., Seoul (KR)

(21) Appl. No.: 14/400,724

(22) PCT Filed: May 30, 2013
(86) PCT No.: PCT/KR2013/004769

§ 371 Date: Nov. 12, 2014

(30) Foreign Application Priority Data
May 30, 2012 (KR) 10-2012-0057178

(51) Int. Cl. H01L 31/049

(52) U.S. Cl. CPC H01L 31/049

(57) ABSTRACT

Solar cell module includes a solar cell panel; a protective substrate on the solar cell panel; a buffer part between the solar cell panel and the protective substrate; and a frame receiving the solar cell panel. The frame includes a side surface part surrounding side surfaces of the solar cell panel and protective substrate, and an inserting part bent from the side surface part. Method of manufacturing solar cell module includes preparing a solar cell panel; placing a buffer part on the solar cell panel; placing the solar cell panel and buffer part in a frame; placing a protective substrate on the buffer part; laminating the buffer part. The frame includes a side surface part and an inserting part crossing the side surface part, the solar cell panel is placed at low portion of the inserting part, and the protective substrate is placed at upper portion of the inserting part.

### TECHNICAL FIELD

The embodiment relates to a solar cell module and a method of manufacturing the same.

### BACKGROUND ART

A solar cell module for converting light energy into electrical energy through photoelectric conversion effect has been extensively used as a device for obtaining non-pollution energy, which contributes to the conservation of global environment.

As the photoelectric conversion effect of a solar cell is improved, a great number of solar cell systems having a solar cell module are installed even for home use.

In order to output power generated from the solar cell module including solar cells that generate power from the light of the sun to an outside, conductors acting as positive and negative electrodes are provided in the solar cell module, and ends of the conductors, which serve as terminals connected to a cable for outputting current to the outside, are withdrawn out from a photovoltaic module.

There is provided a frame for receiving such a solar cell module. The frame is exposed toward a top surface of a protective substrate for protecting the solar cell module, so that the frame is harmful to an outer appearance. Further, foreign substances are stacked on the flame exposed toward the top surface of the protective substrate, so that the solar cell module may be polluted, thereby deteriorating the reliability of the solar cell module.

In addition, in a case of a solar cell module having a typical structure, reliability of the solar cell module is frequently degraded due to penetration of moisture into a periphery of the solar cell module.

### DISCLOSURE

### Technical Problem

The embodiment provides a solar cell module having improved reliability and a method of manufacturing the same.

### Technical Solution

According to the embodiment, there is provided a solar cell module including a solar cell panel; a protective substrate on the solar cell panel; a buffer part between the solar cell panel and the protective substrate; and a frame to receive the solar cell panel, wherein the frame comprises a side surface part surrounding side surfaces of the solar cell panel and the protective substrate, and an inserting part bent from the side surface part.

According to the embodiment, there is provided a method of manufacturing a solar cell module, which includes preparing a solar cell panel; placing a buffer part on the solar cell panel; placing the solar cell panel and the buffer part in a frame; placing a protective substrate on the buffer part; and laminating the buffer part, wherein the frame includes a side surface part and an inserting part crossing the side surface part, the solar cell panel is placed at a low portion of the inserting part, and the protective substrate is placed at an upper portion of the inserting part.

### Advantageous Effects

Accordingly, the route of moisture penetration through the lower substrate becomes long so that moisture penetration into the solar cell module may be minimized. The solar cell module according to the embodiment includes the frame which includes the side surface part surrounding the side surfaces of the solar cell panel and the protective substrate and the inserting part placed to be bent from the side surface part. One end of the side surface part is placed on the same plane with the protective substrate. That is, the frame may not be exposed toward top surface of the protective substrate. Thus, when viewing the solar cell module from the front of the solar cell module, the frame 100 may be rarely seen. Thus, a build-integrated solar cell module may be applied to a BIPV system used as a construction external material. In addition, the outer appearance may be improved. Therefore, since the frame is exposed toward the top surface of the protective substrate, foreign substances may be prevented from being stacked. That is, the reliability of the solar cell module may be improved.

The inserting part may support the solar cell panel and the protective substrate. That is, the inserting part may fix the solar cell panel and the protective substrate, such that the solar cell panel and the protective substrate do not cross each other. Thus, the structural stability of the solar cell module may be maintained.

Then, the sealing part surrounding the frame is further placed, so that moisture is prevented from penetrating into the solar cell module through an edge of the solar cell module. That is, a moisture penetration path is lengthened due to the sealing part, so that the moisture penetrating into the solar cell module can be minimized. Therefore, the reliability of the solar cell module may be improved.

In addition, as compared with a related art where four frames are inserted into each edge and then fixed by bolts or keys, the frame structure may be more simplified. Thus, coupling of the frame may be simplified.

The method of manufacturing a solar cell module according to the embodiment includes the step of performing the lamination, and the buffer part may be laminated in the step of performing the lamination. In this case, the sealing part may be laminated together in the step of performing the lamination. That is, in the step of performing the lamination, the sealing part may be filled inward for sealing caused by up-down pressure and heat. Thus, the frame treating process and the lamination process may be performed at the same time. Therefore, the process may be simplified and the processing time may be reduced.

### DESCRIPTION OF DRAWINGS

FIG. 1 is an exploded perspective view showing a solar cell module according to an embodiment.

FIG. 2 is a plan view showing a frame included in a solar cell module according to an embodiment.

FIG. 3 is a sectional view taken along line B-B′ of FIG. 2.

FIG. 4 is a sectional view taken along line A-A′ of FIG. 1.

### BEST MODE

### Mode for Invention

In the description of the embodiments, it will be understood that, when a layer (or film), a region, a pattern, or a structure is referred to as being “on” or “under” another substrate, another layer (or film), another region, another pad, or another pattern, it can be “directly” or “indirectly” on the other substrate, layer (or film), region, pad, or pattern, or one or more intervening layers may also be present. Such a position of the layer has been described with reference to the drawings.

The thickness and size of each layer (or film), each region, each pattern, or each structure shown in the drawings may be exaggerated, omitted or schematically drawn for the convenience or clarity of explanation. In addition, the size of the layer (or film), the region, the pattern, or the structure does not utterly reflect an actual size.

Hereinafter, the embodiment will be described with reference to accompanying drawings in detail.

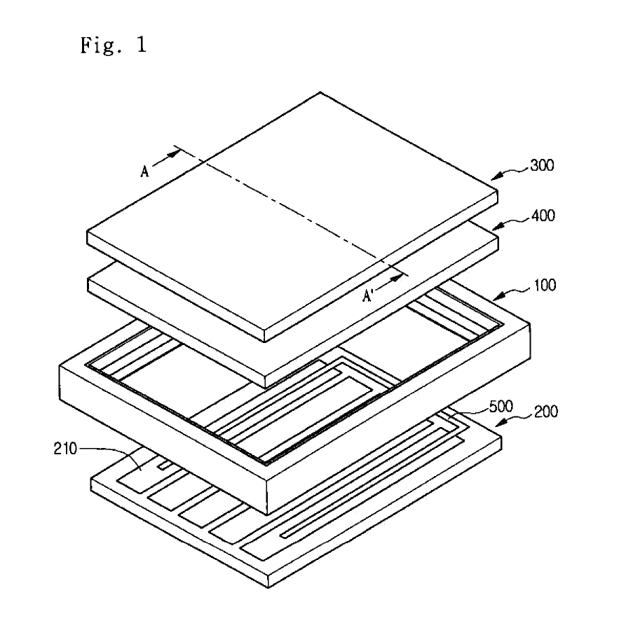

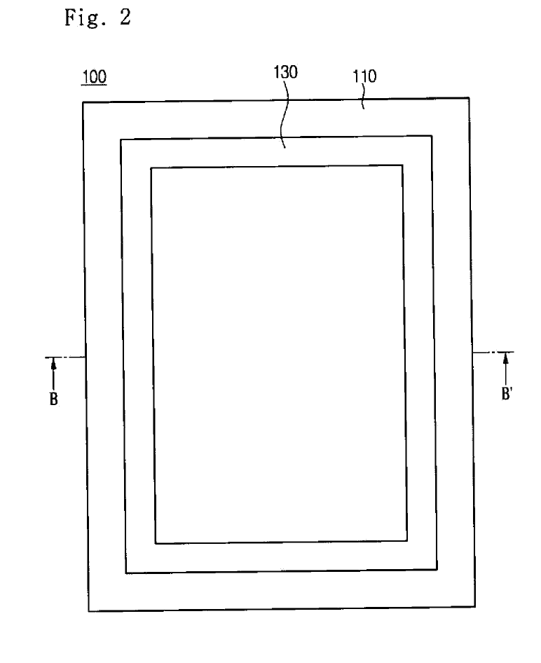

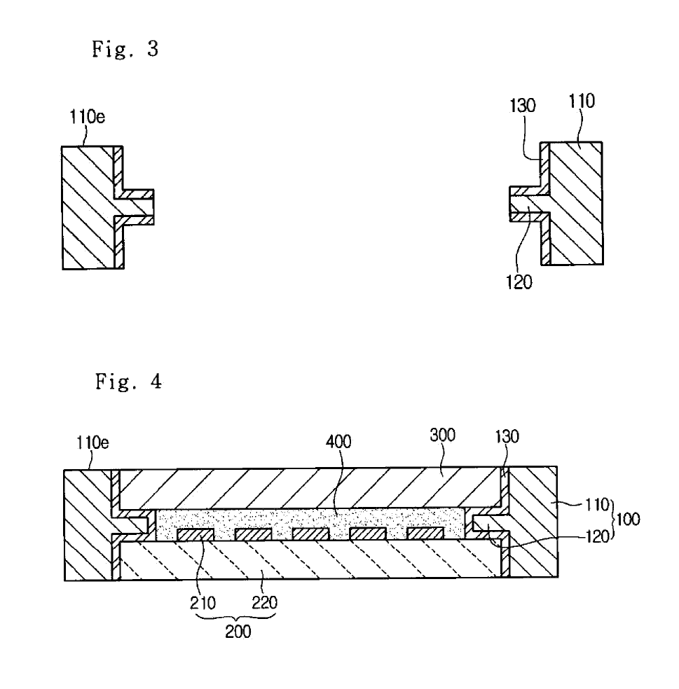

A solar cell module according to the embodiment will be described in detail with reference to FIGS. 1 to 4. FIG. 1 is an exploded perspective view showing a solar cell module according to an embodiment. FIG. 2 is a plan view showing a frame included in a solar cell module according to an embodiment. FIG. 3 is a sectional view taken along line B-B′ of FIG. 2. FIG. 4 is a sectional view taken along line A-A′ of FIG. 1.

The frame 100 is provided outside the solar cell panel 200. The frame 100 receives the solar cell panel 200, the protective substrate 300, and the buffer part 400. In more detail, the frame 100 surrounds a side surface of the solar cell panel 200.

For example, the frame 100 may be a metal frame 100. In addition, the frame 100 may include aluminum, stainless steel or iron.

The frame 100 includes a side surface part and an inserting part 120.

In detail, the side surface part 110 may surround side surfaces of the solar cell panel 200 and the protective substrate 300. The side surface part 110 may surround all the side surfaces of the solar cell panel 200 and the protective substrate 300.

One end 110e of the side surface part 110 is placed on the same plane with the protective substrate 300. That is, the frame 100 may not be exposed toward a top surface of the protective substrate 300. Thus, when viewing the solar cell module from the front of the solar cell module, the frame 100 may be rarely seen. Thus, a build-integrated solar cell module may be applied to a BIPV system used as a construction external material. In addition, the outer appearance may be improved. Therefore, since the frame 110 is exposed toward the top surface of the protective substrate 300, foreign substances may be prevented from being stacked. That is, the protective substrate 300 is prevented from being polluted, so that the reliability of the solar cell module may be improved.

The inserting part 120 is placed while being bent from the side surface part 110. The inserting part 120 is bent at a central portion of the side surface part 110 toward an inside of the side surface part 110. The inserting part 120 is placed along the inside of the side surface part 110. The inserting part 120 is placed along all the surfaces of the side surface part 110.

The side surface par 110 and the inserting part 120 cross each other. Thus, the inserting part 120 and the side surface part 110 are aligned on mutually different planes.

The inserting part 120 is bent at the central portion of the side surface part 110 toward the inside of the side surface part 110. Thus, the inserting part 120 may be placed between the solar cell panel 200 and the protective substrate 300. In more detail, the protective substrate 120 is placed at an upper portion of the inserting part 120 and the solar cell panel 200 is placed at a low portion of the inserting part 120.

The inserting part 120 may support the solar cell panel 200 and the protective substrate 300. That is, the inserting part 120 may fix the solar cell panel 200 and the protective substrate 300 to allow the solar cell panel 200 and the protective substrate 300 not to cross each other. Thus, the structural stability of the solar cell module may be maintained.

The side surface part 110 and the inserting part 120 may be formed integrally with each other.

A thickness of the side surface part 110 and an insertion length of the inserting part 120 may vary according to a using purpose and using environment

The solar cell panel 200 is disposed at an inside of the frame 100. In detail, the solar cell panel 200 is placed at a low portion of the inserting part 120.

Next, a sealing part 130 surrounding the frame 100 is further placed. The frame 100 may be integrated with the sealing part 130. The sealing part 130 surrounds the inner side surface of the side surface part 110 and the inserting part 120.

The sealing part 130 may surround an entire surface of the inserting part 120.

The sealing part 130 may include butyl.

The sealing part 130 may prevent moisture from penetrating into the solar cell module through an edge of the solar cell module. That is, a moisture penetration path is lengthened due to the sealing part 130, so that the moisture penetrating into the solar cell module may be minimized. Therefore, the reliability of the solar cell module may be improved.

In addition, as compared with a related art where four frames are inserted into each edge and then fixed by bolts or keys, the frame structure may be more simplified. Thus, coupling of the frame may be simplified.

The solar cell panel 200 has a plate shape. The solar cell panel 200 includes a plurality of solar cells 210 and a low substrate 220 supporting the solar cells 210.

For example, the solar cells 210 may include a CIGS-based solar cell, a silicon-based solar cell, a dye-sensitized solar cell, a group II-VI compound semiconductor solar cell, or a group III-V compound semiconductor solar cell.

In addition, the solar cells 210 may be disposed on a transparent substrate such as a glass substrate.

The solar cells 210 may be arranged in the shape of a stripe. In addition, the solar cells 210 may be arranged in various shapes such as a matrix shape.

The bus bar 500 is disposed on the solar cell panel 200. The bus bar 500 makes contact with the top surfaces of two of the solar cells 210 and is electrically connected to the solar cells 210.

For example, the bus bar 500 includes a first bus bar and a second bus bar.

The first bus bar makes contact with a top surface of one outermost solar cell and the second bus bar makes contact with a top surface of an opposite outermost solar cell of the solar cells 210.

The bus bar 500 may include a conductor, and for example, the material constituting the bus bar 500 may include copper.

The low substrate 220 may support the solar cells 210. The low substrate 220 may include a glass, metal or plastic material.

Meanwhile, the protective substrate 300 is disposed over the solar cell panel 200. In detail, the protective substrate 300 is disposed to face the solar cell panel 200. The protective substrate is placed at an upper portion of the inserting part 120.

The protective substrate 300 may be transparent and have a high strength. For example, the material constituting the protective substrate 300 may include tempered glass.

The buffer part 400 is interposed between the protective substrate 300 and the solar cell panel 200. The buffer part 400 protects the solar cell panel 200 from the external physical shock. In addition, the buffer part 400 prevents the protective substrate 300 from colliding with the solar cell panel 200.

The buffer part 400 may perform an anti-reflective function so that a greater quantity of light is incident upon the solar cell panel 200.

The buffer part 400 may include an insulator. In detail, the buffer part 400 may be formed of an insulator. For example, the material constituting the buffer part 400 may include ethylene vinyl acetate (EVA) resin. That is, the buffer layer 400 may be an insulating layer.

Hereinafter, a method of manufacturing a solar cell module according to an embodiment will be described. In the following description, the details of the parts the same as or extremely similar to the above-described the parts will be omitted for the purpose of clear and simple explanation.

The method of manufacturing a solar cell module according to an embodiment includes a step of preparing a solar cell panel, a step of placing a buffer part, a step of placing a frame, and a step of placing a protective substrate, and a step of performing lamination.

First, in the step of preparing the solar cell panel, the solar cell panel including a low substrate and a plurality of solar cells placed on the low substrate is prepared.

Then, in the step of placing the buffer part, the buffer part may be placed on the solar cell panel.

In the step of placing the frame, the solar cell panel and the buffer part may be placed in the frame. In this case, the frame includes a side surface part and an inserting part placed to cross the side surface part. Thus, the solar cell panel may be placed at a low portion of the inserting part.

In the step of placing the protective substrate, the protective substrate may be placed on the buffer part. In this case, the protective substrate may be placed at an upper portion of the inserting part.

The solar cell panel and the protective substrate may be fixed by the inserting part. In addition, when the solar cell module is manufactured, an additional fixing jig, which is used to prevent the misalignment between the solar cell panel and the protective substrate, may be omitted.

Then, in the step of performing the lamination, the buffer part may be laminated. In this case, a sealing part surrounding the inserting part may be further provided and the sealing part may be laminated together in the step of performing the lamination. That is, in the step of performing the lamination, the sealing part may be filled inward for sealing by up-down pressure and heat. Thus, the frame treating process and the lamination process may be performed at the same time. Therefore, the process may be simplified and the processing time may be reduced.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell module comprising:
a solar cell panel;
a protective substrate on the solar cell panel;
a buffer part between the solar cell panel and the protective substrate; and
a frame to receive the solar cell panel,
wherein the frame comprises a side surface part surrounding side surfaces of the solar cell panel and the protective substrate, and an inserting part bent from the side surface part.

2. The solar cell module of claim 1, wherein the inserting part is placed between the solar cell panel and the protective substrate.

3. The solar cell module of claim 1, wherein the protective substrate is placed at an upper portion of the inserting part.

4. The solar cell module of claim 1, wherein the solar cell panel is placed at a low portion of the inserting part.

5. The solar cell module of claim 1, wherein the inserting part is placed along an inside of the side surface part.

6. The solar cell module of claim 1, wherein the side surface part and the inserting part cross each other.

7. The solar cell module of claim 1, wherein one end of the side surface is placed on a same plane with the protective substrate.

8. The solar cell module of claim 1, wherein the inserting part supports the solar cell panel and the protective substrate.

9. The solar cell module of claim 1, wherein the side surface part and the inserting part are formed integrally with each other.

10. The solar cell module of claim 1, further comprising a sealing part surrounding the frame.

11. The solar cell module of claim 10, wherein the sealing part surrounds an inner side surface of the side surface part and the inserting part.

12. The solar cell module of claim 10, wherein the sealing part surrounds an entire surface of the inserting part.

13. The solar cell module of claim 10, wherein the sealing part includes butyl.

14. (canceled)

15. (canceled)

16. (canceled)
